(19) United States
(12) Patent Application Publication
(10) Pub. No.: US 2020/0333707 A1
(43) Pub. Date: Oct. 22, 2020

(54) RESIST PATTERN-FORMING METHOD, AND RADIATION-SENSITIVE COMPOSITION AND PRODUCTION METHOD THEREOF

(71) Applicant: JSR CORPORATION, Tokyo (JP)

(72) Inventors: Miki Tamada, Tokyo (JP); Sousuke Oosawa, Tokyo (JP); Ken Maruyama, Tokyo (JP)

(73) Assignee: JSR CORPORATION, Tokyo (JP)

(21) Appl. No.: 16/853,857

(22) Filed: Apr. 21, 2020

(30) Foreign Application Priority Data
Apr. 22, 2019 (JP) 2019-081255
Apr. 3, 2020 (JP) 2020-067675

(51) Int. Cl. G03F 7/004; G03F 7/16; G03F 7/20; G03F 7/32

(52) U.S. Cl. CPC G03F 7/0044; G03F 7/0045; G03F 7/325; G03F 7/168; G03F 7/2037; G03F 7/162

(57) ABSTRACT

A resist pattern-forming method includes applying a radiation-sensitive composition directly or indirectly on a substrate to form a resist film. The resist film is exposed to an extreme ultraviolet ray or an electron beam. The resist film is developed after the exposing. The radiation-sensitive composition includes a first complex, a compound and a second complex. The first complex includes a metal atom and a first ligand coordinating to the metal atom. The compound gives a second ligand that differs from the first ligand. The second complex includes the metal atom and the second ligand coordinating to the metal atom.

### CROSS-REFERENCE TO RELATED APPLICATIONS

The present application claims priority to Japanese Patent Application No. 2019-081255, filed Apr. 22, 2019 and to Japanese Patent Application No. 2020-067675, filed Apr. 3, 2020. The contents of these applications are incorporated herein by reference in their entirety.

### BACKGROUND OF THE INVENTION

### Field of Invention

The present invention relates to a resist pattern-forming method, and a radiation-sensitive composition and a production method thereof.

### Discussion of the Background

General radiation-sensitive compositions for use in microfabrication by lithography generate acids at light-exposed regions upon an exposure to an electromagnetic wave such as a far ultraviolet ray (e.g., ArF excimer laser beam, KrF excimer laser beam, etc.) or an extreme ultraviolet ray, a charged particle ray such as an electron beam, or the like. A chemical reaction in which the acid serves as a catalyst causes a difference in rates of dissolution in a developer solution, between light-exposed regions and light-unexposed regions, to form a resist pattern on a substrate. The resist pattern thus formed can be used as a mask or the like in substrate processing.

Such radiation-sensitive compositions are demanded to have improved resist performance along with miniaturization in processing techniques. To meet such demands, types, molecular structures and the like of polymers, acid generating agents and other components which may be used in the compositions have been investigated, and combinations thereof have been further investigated in detail (see, Japanese Unexamined Patent Application, Publication Nos. H11-125907, H8-146610 and 2000-298347).

Furthermore, improving sensitivity to, in particular, an extreme ultraviolet ray or an electron beam has been demanded recently. To meet this demand, use of a complex having a metal atom and a ligand, as a component of a radiation-sensitive composition has been investigated. It is considered that such a complex is capable of generating secondary electrons through absorption of an extreme ultraviolet ray or the like by the metal atom, thereby enabling the sensitivity to be improved.

### SUMMARY OF THE INVENTION

According to an aspect of the present invention, a resist pattern-forming method includes applying a radiation-sensitive composition directly or indirectly on a substrate to form a resist film. The resist film is exposed to an extreme ultraviolet ray or an electron beam. The resist film is developed after the exposing. The radiation-sensitive composition includes a first complex, a compound and a second complex. The first complex includes a metal atom and a first ligand coordinating to the metal atom. The compound gives a second ligand that differs from the first ligand. The second complex includes the metal atom and the second ligand coordinating to the metal atom.

According to another aspect of the present invention, a radiation-sensitive composition includes a first complex, a compound and a second complex. The first complex incudes a metal atom and a first ligand coordinating to the metal atom. The compound gives a second ligand that differs from the first ligand. The second complex includes the metal atom and the second ligand coordinating to the metal atom.

According to further aspect of the present invention, a production method of a radiation-sensitive composition includes mixing a first complex and a compound. The first complex includes a metal atom and a first ligand coordinating to the metal atom. The compound gives a second ligand that differs from the first ligand.

### DESCRIPTION OF EMBODIMENTS

According to one embodiment of the invention, a resist pattern-forming method includes: applying a radiation-sensitive composition (hereinafter, may be also referred to as “radiation-sensitive composition (X)”) directly or indirectly on a substrate (hereinafter, may be also referred to as “applying step”); exposing a resist film formed by the applying step to an extreme ultraviolet ray or an electron beam (hereinafter, may be also referred to as “exposing step”); and developing the resist film after the exposing (hereinafter, may be also referred to as “developing step”), wherein the radiation-sensitive composition (X) contains: a first complex (hereinafter, may be also referred to as “(A1) complex” or “complex (A1)”) having a metal atom (hereinafter, may be also referred to as “metal atom (M)”), and a first ligand (hereinafter, may be also referred to as “ligand (a)”) coordinating to the metal atom (M); a compound (hereinafter, may be also referred to as “(B) compound” or “compound (B)”) that gives a second ligand (hereinafter, may be also referred to as “ligand (b)”) that differs from the ligand (a); and a second complex (hereinafter, may be also referred to as “(A2) complex” or “complex (A2)”) having the metal atom (M), and the ligand (b) coordinating to the metal atom (M).

According to another embodiment of the present invention, a radiation-sensitive composition contains: the complex (A1) having the metal atom (M), and the ligand (a) coordinating to the metal atom (M); the compound (B) that gives the ligand (b) that differs from the ligand (a); and the complex (A2) having the metal atom (M), and the ligand (b) coordinating to the metal atom (M).

According to a still other embodiment of the present invention, a production method of a radiation-sensitive composition includes mixing: the complex (A1) having the metal atom (M), and the ligand (a) coordinating to the metal atom (M); and the compound (B) that gives the ligand (b) that differs from the ligand (a).

The resist pattern-forming method and the radiation-sensitive composition according to the embodiments of the present invention enable a resist pattern with high resolution and less LWR (Line Width Roughness) to be formed. According to the production method of a radiation-sensitive composition of the embodiment of the present invention, the radiation-sensitive composition can be easily obtained. Therefore, these can be suitably used for manufacture of semiconductor devices, for which microfabrication is expected to progress further hereafter, and the like. Hereinafter, the embodiments of the present invention will be explained in detail.

### Resist Pattern-Forming Method

The resist pattern-forming method of the one embodiment of the present invention includes the applying step, the exposing step, and the developing step. In the resist pattern-forming method, the radiation-sensitive composition (X) described later is used as a radiation-sensitive composition.

The resist pattern-forming method enables a resist pattern with high resolution and less LWR to be formed. Although not necessarily clarified and without wishing to be bound by any theory, the reason for achieving the effects described above due to the resist pattern-forming method having the constitution described above may be supposed as in the following, for example. To explain specifically, the radiation-sensitive composition (X) to be used in the resist pattern-forming method contains the complex (A1) and the complex (A2), a ligand of which differs from that of the complex (A1). Due to containing such complexes of two types, which include different ligands from one another, it is believed that the radiation-sensitive composition (X) enables a shape of a metal-containing layer formed by exposing the resist film to an extreme ultraviolet ray or an electron beam to be finer, and consequently, resolution and LWR of a resist pattern thus obtained can be improved.

Hereinafter, each step will be described.

### Applying Step

In this step, the radiation-sensitive composition (X) is applied directly or indirectly on a substrate. The radiation-sensitive composition (X) will be described later. By this step, a coating film of the radiation-sensitive composition (X) is formed on the substrate directly or via another layer. An applying procedure is not particularly limited, and is exemplified by well-known procedures such as spin-coating. The substrate is exemplified by a silicon wafer, a wafer covered with aluminum, and the like.

By subjecting the coating film formed by applying the radiation-sensitive composition (X) directly or indirectly on the substrate to prebaking (PB) as needed, a resist film is formed.

The lower limit of an average thickness of the resist film is preferably 1 nm, more preferably 10 nm, still more preferably 20 nm, and particularly preferably 30 nm. The upper limit of the average thickness is preferably 1,000 nm, more preferably 200 nm, still more preferably 100 nm, and particularly preferably 50 nm.

The lower limit of a temperature for the PB is preferably 60° C., and more preferably 80° C. The upper limit of the temperature is preferably 140° C., and more preferably 120° C. The lower limit of a time period for the PB is preferably 5 sec, and more preferably 10 sec. The upper limit of the time period is preferably 600 sec, and more preferably 300 sec.

In the embodiment of the present invention, in order to maximize potential abilities of the radiation-sensitive composition, for example, an organic or inorganic antireflective film may be formed beforehand on the substrate to be used. Furthermore, in order to preclude influences from basic impurities and the like included in an environmental atmosphere, a protective film may be provided on the resist film, for example.

### Exposing Step

In this step, the resist film formed by the applying step is exposed to an extreme ultraviolet ray or an electron beam. Specifically, the resist film is irradiated with an extreme ultraviolet ray or an electron beam through a mask having a predetermined pattern, for example.

After the exposure, post exposure baking (PEB) may be conducted. The lower limit of a temperature for the PEB is preferably 50° C., and more preferably 80° C. The upper limit of the temperature for the PEB is preferably 200° C., and more preferably 170° C. The lower limit of a time period for the PEB is preferably 10 sec, and more preferably 30 sec. The upper limit of the time period for the PEB is preferably 600 sec, and more preferably 300 sec.

### Developing Step

In this step, the resist film exposed by the exposing step is developed. Accordingly, obtaining a resist pattern is enabled. A developer solution for use in the development is exemplified by an aqueous alkali solution, an organic solvent-containing liquid, and the like.

Examples of the aqueous alkali solution include alkaline aqueous solutions prepared by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, etc., and the like.

The lower limit of a proportion of the alkaline compound contained in the aqueous alkali solution is preferably 0.1% by mass, more preferably 0.5% by mass, and still more preferably 1% by mass. The upper limit of the proportion is preferably 20% by mass, more preferably 10% by mass, and still more preferably 5% by mass.

The aqueous alkali solution is preferably an aqueous TMAH solution, and more preferably a 2.38% by mass aqueous TMAH solution.

Examples of the organic solvent which may be contained in the organic solvent-containing liquid include organic solvents exemplified as the solvent (D) of the radiation-sensitive composition (X) described later, and the like.

The organic solvent is preferably an ester solvent, an ether solvent, an alcohol solvent, a ketone solvent and/or a hydrocarbon solvent, more preferably the ketone solvent, and still more preferably methyl amyl ketone.

The lower limit of a proportion of the organic solvent contained in the organic solvent-containing liquid is preferably 80% by mass, more preferably 90% by mass, still more preferably 95% by mass, and particularly preferably 99% by mass.

These developer solutions may be used alone of one type, or in a combination of two or more types thereof. It is to be noted that the development is generally followed by washing with water and/or the like, and drying.

Next, the radiation-sensitive composition (X) will be described.

### Radiation-Sensitive Composition

The radiation-sensitive composition (X) contains the complex (A1), the compound (B), and the complex (A2). The radiation-sensitive composition (X) preferably contains a radiation-sensitive acid generating agent (hereinafter, may be also referred to as “(C) acid generating agent” or “acid generating agent (C)”). Moreover, the radiation-sensitive composition (X) typically contains a solvent (hereinafter, may be also referred to as “(D) solvent” or “solvent (D)”). Furthermore, the radiation-sensitive composition (X) may also contain other component(s) within a range not leading to impairment of the effects of the present invention. The radiation-sensitive resin composition (X) is suitably used for the exposure to an extreme ultraviolet ray or the exposure to an electron beam.

Each component will be described in the following.

### (A1) Complex

The complex (A1) has the metal atom (M), and the ligand (a) coordinating to the metal atom (M).

The “metal atom” as referred to herein means an atom of an element classified as a “metal” in the periodic table. The metal atom (M) is exemplified by metal elements from groups 3 to 16 in the periodic table, and the like.

Examples of the metal atom (M) from group 3 include a scandium atom, an yttrium atom, a lanthanum atom, a cerium atom, and the like.

Examples of the metal atom (M) from group 4 include a titanium atom, a zirconium atom, a hafnium atom, and the like.

Examples of the metal atom (M) from group 5 include a vanadium atom, a niobium atom, a tantalum atom, and the like.

Examples of the metal atom (M) from group 6 include a chromium atom, a molybdenum atom, a tungsten atom, and the like.

Examples of the metal atom (M) from group 7 include a manganese atom, a rhenium atom, and the like.

Examples of the metal atom (M) from group 8 include an iron atom, a ruthenium atom, an osmium atom, and the like.

Examples of the metal atom (M) from group 9 include a cobalt atom, a rhodium atom, an iridium atom, and the like.

Examples of the metal atom (M) from group 10 include a nickel atom, a palladium atom, a platinum atom, and the like.

Examples of the metal atom (M) from group 11 include a copper atom, a silver atom, a gold atom, and the like.

Examples of the metal atom (M) from group 12 include a zinc atom, a cadmium atom, a mercury atom, and the like.

Examples of the metal atom (M) from group 13 include a boron atom, an aluminum atom, a gallium atom, an indium atom, and the like.

Examples of the metal atom (M) from group 14 include a silicon atom, a germanium atom, a tin atom, a lead atom, and the like.

Examples of the metal atom (M) from group 15 include an arsenic atom, an antimony atom, a bismuth atom, and the like.

Examples of the metal atom (M) from group 16 include a selenium atom, a tellurium atom, and the like.

The metal atom (M) is preferably the metal atom (M) from group 3 to group 16, more preferably the metal atom (M) from period 4 to period 7 in group 3 to group 16, still more preferably the metal atom (M) from period 4 to period 7 in group 4 to group 6, and particularly preferably the metal atom (M) from period 4 to period 6 in group 4.

Examples of the ligand (a) include: anionic ligands such as a carboxylate ligand, a sulfonate ligand, a phosphonate ligand, a β-ketoenolate ligand, a halogen ligand, an alkoxy ligand, a phenoxy ligand, and a hydrocarbon ligand; neutral ligands such as a carboxylic acid ligand, an alcohol ligand, an amine ligand, and an ammonia ligand; and the like. Of these, the anionic ligands are preferred, and the carboxylate ligand or the β-ketoenolate ligand is more preferred.

The compound (hereinafter, may be also referred to as “compound (A)”) that gives the ligand (a) is exemplified by an acid (hereinafter, may be also referred to as “acid (I)”), and the like. The “acid” as referred to herein means a substance that is capable of giving a proton to another substance. A common logarithmic value (pKa) of the reciprocal of an acid dissociation constant of the acid (I) is, for example, no less than −5 and no greater than 20. The ligand (a) is derived from the compound (A).

Examples of the acid (I) include: oxoacids such as a carboxylic acid and a sulfonic acid; active methylene compounds such as a β-dicarbonyl compound; hydroxy group-containing compounds such as alcohol and phenol compounds; and the like. Of these, the oxoacid or the active methylene compound is preferred, and the carboxylic acid or the β-dicarbonyl compound is more preferred.

The carboxylic acid is exemplified by a monocarboxylic acid, a polycarboxylic acid having at least two carboxy groups, and the like.

Examples of the monocarboxylic acid include:

saturated aliphatic monocarboxylic acids such as formic acid, acetic acid, propionic acid, butyric acid, isobutyric acid, valeric acid, and caproic acid;

unsaturated aliphatic monocarboxylic acids such as acrylic acid, methacrylic acid, crotonic acid, and tiglic acid;

saturated alicyclic monocarboxylic acids such as cyclohexanecarboxylic acid;

unsaturated alicyclic monocarboxylic acids such as cyclohexenecarboxylic acid;

aromatic monocarboxylic acids such as benzoic acid, toluic acid, naphthoic acid, furancarboxylic acid, vinylbenzoic acid, vinylnaphthoic acid, cinnamic acid, and vinylfurancarboxylic acid; and the like.

Examples of the polycarboxylic acid include:

saturated aliphatic polycarboxylic acids such as oxalic acid, malonic acid, succinic acid, glutaric acid, adipic acid, and propane-1,2,3-tricarboxylic acid;

unsaturated aliphatic polycarboxylic acids such as maleic acid, fumaric acid, and propene-1,2,3-tricarboxylic acid;

saturated alicyclic polycarboxylic acids such as cyclohexane-1,4-dicarboxylic acid;

unsaturated alicyclic polycarboxylic acids such as cyclohexene-1,4-dicarboxylic acid;

aromatic polycarboxylic acids such as phthalic acid, terephthalic acid, naphthalene-2,6-dicarboxylic acid, naphthalene-2,7-dicarboxylic acid, furan-2,5-dicarboxylic acid, trimellitic acid, pyromellitic acid, 4-vinylphthalic acid, 3-vinylfuran-2,5-dicarboxylic acid, and 6-vinylbenzene-1,2,4-tricarboxylic acid; and the like.

Examples of the sulfonic acid include methanesulfonic acid, benzenesulfonic acid, and the like.

The β-dicarbonyl compound is exemplified by a β-diketone, a β-ketoester, a β-dicarboxylic acid ester, and the like.

Examples of the β-diketone include acetylacetone, 3-methyl-2,4-pentanedione, 3-ethyl-2,4-pentanedione, 2,2-dimethyl-3,5-hexanedione, and the like.

Examples of the β-ketoester include an acetoacetic acid ester, an α-alkyl-substituted acetoacetic acid ester, a β-ketopentanoic acid ester, a benzoyl acetic acid ester, a 1,3-acetonedicarboxylic acid ester, and the like.

Examples of the β-dicarboxylic acid ester include diester malonate, α-alkyl-substituted diester malonate, α-cycloalkyl-substituted diester malonate, α-aryl-substituted diester malonate, and the like.

Examples of the alcohol include methanol, ethanol, n-propanol, i-propanol, n-butanol, i-butanol, sec-butanol, t-butanol, and the like.

Examples of the phenol compound include phenol, t-butylphenol, naphthol, and the like.

The lower limit of the pKa of the acid (I) is preferably 0, more preferably 2, still more preferably 4, and particularly preferably 4.7. The upper limit of the pKa is preferably 10, and more preferably 9.

The lower limit of a proportion of the complex (A1) with respect to total components other than the solvent (D) in the radiation-sensitive composition (X) is preferably 1% by mass, more preferably 5% by mass, and still more preferably 10% by mass. The upper limit of the proportion is preferably 60% by mass, more preferably 50% by mass, and still more preferably 40% by mass.

The lower limit of a proportion of the complex (A1) contained in the radiation-sensitive composition (X) is preferably 0.01% by mass, more preferably 0.1% by mass, and still more preferably 0.5% by mass. The upper limit of the proportion is preferably 10% by mass, more preferably 5% by mass, and still more preferably 3% by mass. One, or two or more types of the complex (A1) may be used.

The complex (A1) can be obtained by, for example, allowing a metal compound having a hydrolyzable group to react with the compound (A) in the presence of water, in a solvent such as tetrahydrofuran. Examples of the hydrolyzable group include: alkoxy groups such as a methoxy group, an ethoxy group, and a butoxy group; halogen atoms such as a chlorine atom and a bromine atom; and the like.

Examples of the metal compound having a hydrolyzable group include:

metal compounds having four hydrolyzable groups such as tetrabutyl orthotitanate, tetra-i-propyl orthotitanate, tetraethyl orthotitanate, tetramethyl orthotitanate, zirconium(IV) tetrabutoxide, zirconium(IV) tetra-i-propoxide, zirconium(IV) tetraethoxide, zirconium(IV) tetramethoxide, hafnium(IV) tetra-n-butoxide, hafnium(IV) tetra-i-propoxide, hafnium(IV) tetraethoxide, and hafnium(IV) tetramethoxide;

metal compounds having three hydrolyzable groups such as methyltrimethoxytitanium, methyltriethoxytitanium, methyltri-i-propoxytitanium, methyltributoxyzirconium, methyltrimethoxyzirconium, ethyltriethoxyzirconium, ethyltri-i-propoxyzirconium, ethyltributoxyzirconium, butyltrimethoxytitanium, phenyltrimethoxytitanium, naphthyltrimethoxytitanium, phenyltriethoxytitanium, naphthyltriethoxytitanium, aminopropyltrimethoxytitanium, aminopropyltriethoxyzirconium, 2-(3,4-epoxycyclohexyl)ethyltrimethoxyzirconium, γ-glycidoxypropyltrimethoxyzirconium, 3-isocyanopropyltrimethoxyzirconium, 3-isocyanopropyltriethoxyzirconium, triethoxymono(acetylacetonate)titanium, tri-n-propoxymono(acetylacetonate)titanium, tri-i-propoxymono(acetylacetonate)titanium, triethoxymono(acetylacetonate)zirconium, tri-n-propoxymono(acetylacetonate)zirconium, tri-i-propoxymono(acetylacetonate)zirconium, and titanium tributoxymonostearate;

metal compounds having two hydrolyzable groups such as dimethyldimethoxytitanium, diphenyldimethoxytitanium, dibutyldimethoxyzirconium, diiopropoxybisacetylacetonate, di-n-butoxybis(acetylacetonate)titanium, and di-n-butoxybis(acetylacetonate)zirconium;

metal compounds having one hydrolyzable group such as trimethylmethoxytitanium, triphenylmethoxytitanium, tributylmethoxytitanium, tri(3-methacryloxypropyl)methoxyzirconium, and tri(3-acryloxypropyl)methoxyzirconium;

hydrolysates of the aforementioned metal compounds, hydrolytic condensation products of the aforementioned metal compounds, any combination of the same, and the like.

The metal compound having a hydrolyzable group is preferably the metal compound having two, three or four hydrolyzable groups, a hydrolysate thereof, a hydrolytic condensation product thereof or a combination of the same, more preferably the metal compound having four hydrolyzable groups, a hydrolysate thereof, a hydrolytic condensation product thereof or a combination of the same, and still more preferably the metal compound having four hydrolyzable groups.

In a case in which the complex (A1) is particles, the lower limit of a particle diameter of the particles of the complex (A1) is preferably 0.1 nm, more preferably 0.3 nm, still more preferably 0.5 nm, and particularly preferably 0.7 nm. The upper limit of the particle diameter is preferably 10 nm, more preferably 5 nm, still more preferably 3 nm, and particularly preferably 2 nm. The particle diameter of particles of a complex is a value determined by using a light scattering measurement apparatus (for example, “ALV-5000” available from ALV GmbH, Germany, and the like), under a condition involving a detection angle of 60° and a time period of the measurement of 120 sec.

### (B) Compound

The compound (B) is a compound that gives the ligand (b) of the complex (A2) described later. The ligand (b) of the complex (A2) is different from the ligand (a) of the complex (A1) described above. In other words, the compound (B) is different from the compound (A) that gives the ligand (a).

Examples of the compound (B) include, among the compounds exemplified as the compound (A) in the section (A1) Complex, compounds that differ from the compound (A) that gives the ligand (a) of the complex (A1), and the like.

In a case in which the ligand (a) of the complex (A1) does not have a polymerizable group, it is preferred that the ligand (b) of the complex (A2) has a polymerizable group such as a vinyl group, an allyl group, or a (meth)acryloyl group. In other words, in the case in which the ligand (a) of the complex (A1) does not have a polymerizable group, the compound (B) is preferably the compound having a polymerizable group. Due to providing such a combination of the ligand (a) and the ligand (b), generation of bonds between the polymerizable groups is believed to appropriately occur by an exposure, and as a result, resolution and LWR can be further improved.

Examples of the compound having a polymerizable group include: the compounds exemplified as the unsaturated aliphatic monocarboxylic acid, the unsaturated alicyclic monocarboxylic acid, the unsaturated aliphatic polycarboxylic acid and the unsaturated alicyclic polycarboxylic acid in connection with the compound (A) that gives the ligand (a) of the complex (A1); aromatic monocarboxylic acids having a polymerizable group such as vinylbenzoic acid, vinylnaphthoic acid, and vinylfurancarboxylic acid; aromatic polycarboxylic acids having a polymerizable group such as 4-vinylphthalic acid, 3-vinylfuran-2,5-dicarboxylic acid, and 6-vinylbenzene-1,2,4-tricarboxylic acid; and the like.

The compound having a polymerizable group is preferably a carboxylic acid having a polymerizable group, more preferably an unsaturated carboxylic acid, still more preferably an unsaturated aliphatic monocarboxylic acid or an aromatic monocarboxylic acid having a polymerizable group, and particularly preferably methacrylic acid or vinylbenzoic acid.

In a case in which the ligand (a) of the complex (A1) and the ligand (b) of the complex (A2) are both derived from the acid (I), it is preferred that a pKa of the acid (I) that gives the ligand (b) (hereinafter, may be also referred to as “acid (I-b)”) is smaller than a pKa of the acid (I) that gives the ligand (a) (hereinafter, may be also referred to as “acid (I-a)”). In other words, a pKa of the compound (B) is preferably smaller than a pKa of the compound (A). By providing such a combination of the ligand (a) and the ligand (b), ligand exchange between the ligand (a) and the compound (B) is believed to more appropriately occur, and as a result, resolution and LWR can be further improved.

In a case in which the compound (B) is the acid (I), the lower limit of the pKa of the compound (B) is preferably 0, more preferably 2, and still more preferably 4. The upper limit of the pKa is preferably 10, more preferably 9, still more preferably 5, and particularly preferably 4.7.

The lower limit of a value obtained by subtracting the pKa of the compound (B) from the pKa of the compound (A) is preferably 0.1, more preferably 0.15, still more preferably 0.3, and particularly preferably 0.4. The upper limit of the value is preferably 10, more preferably 4, and still more preferably 1.

The lower limit of a proportion of the compound (B) with respect to total components other than the solvent (D) in the radiation-sensitive composition (X) is preferably 0.1% by mass, more preferably 1% by mass, still more preferably 10% by mass, and particularly preferably 25% by mass. The upper limit of the proportion is preferably 80% by mass.

The lower limit of a content of the compound (B) with respect to 100 parts by mass of the complex (A) is preferably 5 parts by mass, more preferably 15 parts by mass, and still more preferably 30 parts by mass. The upper limit of the content is preferably 700 parts by mass, more preferably 600 parts by mass, and still more preferably 500 parts by mass. One, or two or more types of the compound (B) may be used.

### (A2) Complex

The complex (A2) has the metal atom (M), and the ligand (b) coordinating to the metal atom (M). The complex (A2) may have as a ligand other than the ligand (b), a ligand identical to the ligand (a) that the complex (A1) has.

The lower limit of a proportion of the complex (A2) with respect to total components other than the solvent (D) in the radiation-sensitive composition (X) is preferably 1% by mass, more preferably 5% by mass, and still more preferably 10% by mass. The upper limit of the proportion is preferably 60% by mass, more preferably 50% by mass, and still more preferably 40% by mass.

The lower limit of a proportion of the complex (A2) contained in the radiation-sensitive composition (X) is preferably 0.01% by mass, more preferably 0.1% by mass, and still more preferably 0.5% by mass. The upper limit of the proportion is preferably 10% by mass, more preferably 5% by mass, and still more preferably 3% by mass.

The lower limit of a ratio of the number of moles of the complex (A2) to the number of moles of the complex (A1) is preferably 0.01, more preferably 0.1, still more preferably 0.2, and particularly preferably 0.5. The upper limit of the ratio is preferably 100, more preferably 10, still more preferably 5, and particularly preferably 2.

The lower limit of a proportion of a total of the complex (A1) and the complex (A2) with respect to total components other than the solvent (D) in the radiation-sensitive composition (X) is preferably 2% by mass, more preferably 5% by mass, still more preferably 10% by mass, and particularly preferably 15% by mass. The upper limit of the proportion is preferably 90% by mass, more preferably 80% by mass, still more preferably 70% by mass, and particularly preferably 60% by mass.

The lower limit of a proportion of a total of the complex (A1) and the complex (A2) contained in the radiation-sensitive composition (X) is preferably 0.01% by mass, more preferably 0.1% by mass, still more preferably 0.5% by mass, and particularly preferably 1% by mass. The upper limit of the proportion is preferably 30% by mass, more preferably 20% by mass, still more preferably 10% by mass, and particularly preferably 5% by mass.

The complex (A2) is typically formed by ligand exchange between the ligand (a) of the complex (A1), and the compound (B) that gives the ligand (b).

In a case in which the complex (A2) is particles, the lower limit of a particle diameter of the particles of the complex (A2) is preferably 0.1 nm, more preferably 0.3 nm, still more preferably 0.5 nm, and particularly preferably 0.7 nm. The upper limit of the particle diameter is preferably 10 nm, more preferably 5 nm, still more preferably 3 nm, and particularly preferably 2 nm.

In a case in which the complex (A1) and the complex (A2) are both particles, the lower limit of a particle diameter of the particles of the complex (A1) and the complex (A2) is preferably 0.1 nm, more preferably 0.3 nm, still more preferably 0.5 nm, and particularly preferably 0.7 nm. The upper limit of the particle diameter is preferably 10 nm, more preferably 5 nm, still more preferably 3 nm, and particularly preferably 2 nm.

### (C) Acid Generating Agent

The acid generating agent (C) is a component that generates an acid by an irradiation with a radioactive ray. The action of the acid generated from the acid generating agent (C) is able to further promote change of solubility, etc. in the developer solution of the complex (A) in the radiation-sensitive composition (X), and as a result, the resolution and LWR can be further improved.

The acid generating agent (C) is exemplified by an onium salt compound, an N-sulfonyloxyimide compound, a halogen-containing compound, a diazo ketone compound, and the like.

Exemplary onium salt compounds may include a sulfonium salt, a tetrahydrothiophenium salt, an iodonium salt, a phosphonium salt, a diazonium salt, a pyridinium salt, and the like.

Examples of the sulfonium salt include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, triphenylsulfonium camphorsulfonate, 4-cyclohexylphenyldiphenylsulfonium nonafluoro-n-butanesulfonate, 4-methanesulfonylphenyldiphenylsulfonium nonafluoro-n-butanesulfonate, triphenylsulfonium 1,1,2,2-tetrafluoro-6-(1-adamantanecarbonyloxy)-hexane-1-sulfonate, triphenylsulfonium 2-(1-adamantyl)-1,1-difluoroethanesulfonate, triphenylsulfonium 2-(adamantan-1-ylcarbonyloxy)-1,1,3,3,3-pentafluoropropane-1-sulfonate, and the like.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(4-n-butoxynaphthalen-1-yl)tetrahydrothiophenium camphorsulfonate, 1-(6-n-butoxynaphthalen-2-yl)tetrahydrothiophenium nonafluoro-n-butanesulfonate, 1-(3,5-dimethyl-4-hydroxyphenyl)tetrahydrothiophenium nonafluoro-n-butanesulfonate, and the like.

Examples of the iodonium salt include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, diphenyliodonium camphorsulfonate, bis(4-t-butylphenyl)iodonium nonafluoro-n-butanesulfonate, and the like.

Examples of the N-sulfonyloxyimide compound include N-trifluoromethylsulfonyloxyphthalimide, N-(trifluoromethylsulfonyloxy)-1,8-naphthalimide, N-(trifluoromethylsulfonyloxy)bicyclo[2.2.1]hept-5-ene-2,3-dicarboxyimide, N-(nonafluoro-n-butylsulfonyloxy)bicyclo[2.2.1]hept-5-ene-2,3-dicarboxyimide, N-(perfluoro-n-octylsulfonyloxy)-1,8-naphthalimide, N-(perfluoro-n-octylsulfonyloxy)bicyclo[2.2.1]hept-5-ene-2,3-dicarboxyimide, N-(2-bicyclo[2.2.1]hept-2-yl-1,1,2,2-tetrafluoroethylsulfonyloxy)bicyclo[2.2.1]hept-5-ene-2,3-dicarboxyimide, N-(2-(3-tetracyclo[4.4.0.1^{2,5}1^{7,10}]dodecanyl)-1,1-difluoroethylsulfonyloxy)bicyclo[2.2.1]hept-5-ene-2,3-dicarboxyimide, N-(camphorsulfonyloxy)bicyclo[2.2.1]hept-5-ene-2,3-dicarboxyimide, and the like.

Of these, as the acid generating agent, the N-sulfonyloxyimide compounds are preferred, and N-trifluoromethylsulfonyloxyphthalimide is more preferred.

In the case in which the radiation-sensitive composition (X) contains the acid generating agent (C), the lower limit of a content of the acid generating agent (C) with respect to 100 parts by mass of the complex (A) is preferably 0.1 parts by mass, more preferably 1 part by mass, still more preferably 2 parts by mass, and particularly preferably 5 parts by mass. The upper limit of the content is preferably 100 parts by mass, more preferably 60 parts by mass, still more preferably 50 parts by mass, and particularly preferably 40 parts by mass. When the content of the acid generating agent (C) falls within the above range, the resolution and LWR can be further improved. One, or two or more types of the acid generating agent (C) may be used.

### (D) Solvent

The radiation-sensitive composition (X) commonly contains the solvent (D). The solvent (D) is not particularly limited as long as it is able to dissolve or disperse the complex (A1), the compound (B), and the complex (A2), as well as the acid generating agent (C) and other component(s) that may be contained as needed. The solvent (D) may be used alone of one type, or in a combination of two or more types thereof.

The solvent (D) is exemplified by an alcohol solvent, a ketone solvent, an ether solvent, an ester solvent, a nitrogen-containing solvent, a hydrocarbon solvent, and the like.

Examples of the alcohol solvent include: monohydric alcohol solvents such as methanol, ethanol, and n-propanol; polyhydric alcohol solvents such as ethylene glycol and 1,2-propylene glycol; and the like.

Examples of the ketone solvent include: chain ketone solvents such as methyl ethyl ketone and methyl-iso-butyl ketone; cyclic ketone solvents such as cyclohexanone; and the like.

Examples of the ether solvent include: chain ether solvents such as n-butyl ether; polyhydric alcohol ether solvents, e.g., cyclic ether solvents such as tetrahydrofuran; polyhydric alcohol partial ether solvents such as propylene glycol monomethyl ether; and the like.

Examples of the ester solvent include: carbonate solvents such as diethyl carbonate; mono ester acetate solvents such as methyl acetate and ethyl acetate; lactone solvents such as γ-butyrolactone; polyhydric alcohol partial ether carboxylate solvents such as diethylene glycol monomethyl ether acetate and propylene glycol monomethyl ether acetate; lactic acid ester solvents such as methyl lactate and ethyl lactate; and the like.

Examples of the nitrogen-containing solvent include: nitrogen-containing chain solvents such as N,N-dimethylacetamide; nitrogen-containing cyclic solvents such as N-methylpyrrolidone; and the like.

Examples of the hydrocarbon solvent include: aliphatic hydrocarbon solvents such as decane, cyclohexane, and decahydronaphthalene; aromatic hydrocarbon solvents such as toluene; and the like.

Of these, the ether solvent and/or the ester solvent are/is preferred, the polyhydric alcohol partial ether solvent and/or the polyhydric alcohol partial ether carboxylate solvent are/is more preferred, and propylene glycol monomethyl ether and/or propylene glycol monomethyl ether acetate are/is still more preferred.

In the case in which the radiation-sensitive composition (X) contains the solvent (D), the lower limit of a content of the solvent (D) with respect to 100 parts by mass of the complex (A) is preferably 100 parts by mass, more preferably 500 parts by mass, still more preferably 1,000 parts by mass, and particularly preferably 3,000 parts by mass. The upper limit of the content is preferably 100,000 parts by mass, more preferably 50,000 parts by mass, still more preferably 10,000 parts by mass, and particularly preferably 5,000 parts by mass. One, or two or more types of the solvent (D) may be used.

### Other Components

The radiation-sensitive composition (X) may contain, as other components, for example, a surfactant, an adhesion aid, and the like.

### Production Method of Radiation-Sensitive Composition

The radiation-sensitive composition (X) can be obtained by a production method which includes mixing the complex (A1) and the compound (B), for example. More specifically, the radiation-sensitive composition (X) may be obtained by mixing the complex (A1) and the compound (B), and as needed, the acid generating agent (C), the solvent (D) and the like, preferably followed by filtering a mixed solution through e.g., a filter having a pore size of about 0.2 μm.

By mixing the complex (A1) and the compound (B), ligand exchange between the ligand (a) of the complex (A1), and the compound (B) that gives the ligand (b) results in formation of the complex (A2) having the ligand (b), and thus the radiation-sensitive composition (X) is obtained.

The lower limit of an amount of the compound (B) blended with respect to 100 parts by mass of the complex (A1) is preferably 1 part by mass, more preferably 10 parts by mass, still more preferably 20 parts by mass, and particularly preferably 40 parts by mass. The upper limit of the amount is preferably 10,000 parts by mass, more preferably 3,000 parts by mass, still more preferably 1,000 parts by mass, and particularly preferably 500 parts by mass.

In the case in which the compound (A) that gives the ligand (a) of the complex (A1) is a carboxylic acid not including a polymerizable group, and the compound (B) is a compound including a polymerizable group, the lower limit of the amount of the compound (B) blended with respect to 100 parts by mass of the complex (A1) is preferably 10 parts by mass, more preferably 30 parts by mass, and still more preferably 40 parts by mass. The upper limit of the amount is preferably 300 parts by mass, more preferably 100 parts by mass, and still more preferably 70 parts by mass. When the amount of the compound (B) falls within the above range, the sensitivity can be further improved.

### EXAMPLES

Hereinafter, the present invention is explained in detail by way of Examples, but the present invention is not in any way limited to these Examples. Physical property values in the Examples were measured as described below.

### Measurement of Particle Diameter of Particles of Complex (A)

The particle diameter of the particles of the complex (A) synthesized was measured by using a light scattering measurement apparatus (“ALV-5000” available from ALV GmbH,

Germany), under a condition involving a detection angle of 60° and a time period of the measurement of 120 sec. A sample for the measurement was prepared by mixing 3 parts by mass of the complex (A) and 97 parts by mass of propylene glycol monomethyl ether acetate.

### Synthesis Example 1: Synthesis of Complex (A-1)

Into a nitrogen-substituted 500-mL three-neck flask, 20.0 g of tetrabutyl orthotitanate as a metal alkoxide, 100 mL of tetrahydrofuran, and 100 mL of propionic acid as the compound that gives the ligand (a) were added on an ice bath, and a resulting mixture was stirred for 20 min. After the temperature was elevated to 65° C. and the mixture was stirred for 20 min, 10.6 g of water was added dropwise over 10 min. After the mixture was stirred at 65° C. for 18 hrs, 10.6 g of water was added dropwise again over 10 min. After stirring for 2 hrs, the reaction was terminated by allowing to cool to a normal temperature. To a reaction liquid thus obtained, 400 mL of water was added to allow for precipitation of a complex in a particulate form. The complex precipitated in the particulate form was subjected to centrifugal separation at 3,000 rpm for 10 min followed by decantation of a solution of an upper layer. The complex in the particulate form remained was dissolved in 50 g of acetone, and again precipitation was permitted by adding 400 mL of water. The complex precipitated in the particulate form was subjected to centrifugal separation at 3,000 rpm and decantation of the upper layer was conducted. The complex obtained in the particulate form was dried at 10 Pa for 15 hrs to give 11.2 g of a complex (A-1) in the particulate form. The complex (A-1) had a titanium atom and the ligand (a) derived from propionic acid coordinating to the titanium atom. The particle diameter of the particles of the complex (A-1) was 1.5 nm.

### Synthesis Examples 2 to 8: Syntheses of Complexes (A-2) to (A-8)

Complexes (A-2) to (A-8) were synthesized similarly to Synthesis Example 1 except that each metal alkoxide and each compound (A) that gives the ligand (a), types of which were as shown in Table 1 below, were used. Measurements of particle diameters of the particles of complexes (A-2) to (A-8) are shown together in Table 1 below.

TABLE 1

| | | | Compound (A) | Particle |
|---|---|---|---|---|
| | (A1) | | that gives | diameter |
| | Complex | Metal alkoxide | ligand (a) | (nm) |
| Synthesis | A-1 | tetrabutyl | propionic acid | 1.5 |
| Example 1 | | orthotitanate | | |
| Synthesis | A-2 | zirconium(IV) | propionic acid | 1.3 |
| Example 2 | | tetrabutoxide | | |
| Synthesis | A-3 | zirconium(IV) | acetylacetone | 1.0 |
| Example 3 | | tetrabutoxide | | |
| Synthesis | A-4 | hafnium(IV) | propionic acid | 1.4 |
| Example 4 | | tetra-n-butoxide | | |
| Synthesis | A-5 | hafnium(IV) | acetylacetone | 0.8 |
| Example 5 | | tetra-n-butoxide | | |
| Synthesis | A-6 | tetrabutyl | methacrylic acid | 1.2 |
| Example 6 | | orthotitanate | | |
| Synthesis | A-7 | zirconium(IV) | methacrylic acid | 1.3 |
| Example 7 | | tetrabutoxide | | |
| Synthesis | A-8 | hafnium(IV) | methacrylic acid | 1.4 |
| Example 8 | | tetra-n-butoxide | | |

### Preparation of Radiation-Sensitive Resin Composition

Each of the compound (B), the acid generating agent (C), and the solvent (D) used in preparing the radiation-sensitive resin composition are as shown below.

### (B) Compound

The pKa of each compound (B) is shown together.
B-1: methacrylic acid (pKa: 4.66)
B-2: vinylbenzoic acid (pKa: 4.24)
B-3: propionic acid (pKa: 4.87)
B-4: isobutyric acid (pKa: 4.84)
B-5: acetylacetone (pKa: 8.9)

### (C) Acid Generating Agent

C-1: N-trifluoromethylsulfonyloxyphthalimide (a compound represented by the following formula (C-1))

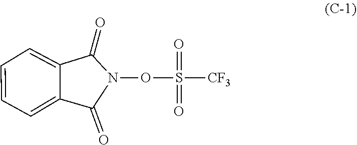 [SMILES: O=C1c2ccccc2C(=O)N1OS(=O)(=O)C(F)(F)F]

### (D) Solvent

D-1: propylene glycol monomethyl ether acetate

D-2: propylene glycol monomethyl ether

### Example 1

A radiation-sensitive composition (R-1) was prepared by blending 100 parts by mass of (A-1) as the complex (A1), 440 parts by mass of (B-1) as the compound (B), 10 parts by mass of (C-1) as the acid generating agent (C), and 2,800 parts by mass of (D-1) and 1,200 parts by mass of (D-2) as the solvent (D), and filtering a resulting mixed solution through a filter having a pore size of 0.2 μm.

### Examples 2 to 8 and Comparative Examples 1 to 9

Radiation-sensitive compositions (R-2) to (R-8) and (CR-1) to (CR-9) were prepared similarly to Example 1 except that each component of the type and in the amount shown in Table 2 below was used. In Table 2, “-” denotes that a corresponding component was not used.

The radiation-sensitive composition (R-1) and the radiation-sensitive composition (CR-1) differ from one another in terms of only the type of the compound (A) that gives the ligand (a) of the complex (A1), whereas types of other components of (R-1) and (CR-1) are identical.

The radiation-sensitive composition (R-2) and the radiation-sensitive composition (CR-2) differ from one another in terms of only the type of the compound (B) that gives the ligand (b), whereas types of other components of (R-2) and (CR-2) are identical.

Similarly, the radiation-sensitive composition (R-n) and the radiation-sensitive composition (CR-n) (n=3 to 8) differ from one another in terms of only the type of one of either the compound (A) that gives the ligand (a) or the compound (B) that gives the ligand (b), whereas types of other components of (R-n) and (CR-n) are identical.

The radiation-sensitive composition (R-6) and the radiation-sensitive composition (CR-9) differ from one another in terms of only the presence/absence of the compound (B) that gives the ligand (b), whereas types of other components of (R-6) and (CR-9) are identical.

TABLE 2

| | Radiation- | (A1) Complex | | (B) Compound | | (C) Acid generating agent | | (D) Solvent | |
|---|---|---|---|---|---|---|---|---|---|
| | sensitive | | Amount (parts | | amount (parts | | amount (parts | | amount (parts |
| | composition | type | by mass) | type | by mass) | type | by mass) | type | by mass) |
| Example 1 | R-1 | A-1 | 100 | B-1 | 440 | C-1 | 10 | D-1/D-2 | 2,800/1,200 |
| Example 2 | R-2 | A-1 | 100 | B-2 | 50 | C-1 | 10 | D-1/D-2 | 2,800/1,200 |
| Example 3 | R-3 | A-2 | 100 | B-1 | 440 | C-1 | 20 | D-1/D-2 | 2,800/1,200 |
| Example 4 | R-4 | A-2 | 100 | B-2 | 50 | C-1 | 20 | D-1/D-2 | 2,800/1,200 |
| Example 5 | R-5 | A-3 | 100 | B-1 | 440 | C-1 | 30 | D-1/D-2 | 2,800/1,200 |
| Example 6 | R-6 | A-4 | 100 | B-1 | 440 | C-1 | 10 | D-1/D-2 | 2,800/1,200 |
| Example 7 | R-7 | A-4 | 100 | B-2 | 50 | C-1 | 10 | D-1/D-2 | 2,800/1,200 |
| Example 8 | R-8 | A-5 | 100 | B-1 | 440 | C-1 | 30 | D-1/D-2 | 2,800/1,200 |
| Comparative Example 1 | CR-1 | A-6 | 100 | B-1 | 440 | C-1 | 10 | D-1/D-2 | 2,800/1,200 |
| Comparative Example 2 | CR-2 | A-1 | 100 | B-3 | 440 | C-1 | 10 | D-1/D-2 | 2,800/1,200 |
| Comparative Example 3 | CR-3 | A-7 | 100 | B-1 | 440 | C-1 | 10 | D-1/D-2 | 2,800/1,200 |
| Comparative Example 4 | CR-4 | A-2 | 100 | B-3 | 440 | C-1 | 10 | D-1/D-2 | 2,800/1,200 |
| Comparative Example 5 | CR-5 | A-3 | 100 | B-5 | 440 | C-1 | 10 | D-1/D-2 | 2,800/1,200 |
| Comparative Example 6 | CR-6 | A-8 | 100 | B-1 | 440 | C-1 | 20 | D-1/D-2 | 2,800/1,200 |
| Comparative Example 7 | CR-7 | A-4 | 100 | B-3 | 440 | C-1 | 20 | D-1/D-2 | 2,800/1,200 |
| Comparative Example 8 | CR-8 | A-5 | 100 | B-5 | 440 | C-1 | 20 | D-1/D-2 | 2,800/1,200 |
| Comparative Example 9 | CR-9 | A-4 | 100 | — | — | C-1 | 10 | D-1/D-2 | 2,800/1,200 |

### Formation of Resist Pattern

The radiation-sensitive composition prepared as described above was applied on a surface of an 8-inch silicon wafer by using a spin coater (“CLEAN TRACK ACTS” available from Tokyo Electron Limited), then subjected to PB at 90° C. for 60 sec followed by cooling at 23° C. for 30 sec to form a resist film having an average thickness of 35 nm. Next, this resist film was irradiated with an electron beam by using a simplified electron beam writer (“HL800D” available from Hitachi, Ltd., output: 50 KeV, electric current density: 5.0 A/cm²). Next, by conducting a development at 23° C. for 30 sec with methyl amyl ketone as an organic solvent-containing developer solution, followed by drying, a negative tone resist pattern was formed.

### Evaluations

On each resist pattern formed by using the radiation-sensitive compositions (R-1) to (R-8) and (CR-1) to (CR-8), the resolution, the LWR and the sensitivity were evaluated in accordance with the following procedures. For line-width measurement of the resist pattern, a scanning electron microscope (“S-9380” available from Hitachi High-Technologies Corporation) was used.

### Resolution

A dimension of a minimum resist pattern formed was measured, and this measurement value was defined as resolution (nm). A smaller value of the resolution indicates a better result.

The values of the resolution were compared between the radiation-sensitive compositions that differ one another in terms of only the presence/absence or only either one of the type of the ligand (a) and the ligand (b). The resolution was evaluated by comparing values of the resolution of the radiation-sensitive composition of the Example and the radiation-sensitive composition of the Comparative Example to be used for comparison with this Example, and the evaluation was made to be: “A” (very favorable) in a case in which the value of the resolution of the Example was smaller than that of the Comparative Example by no less than 20%; “B” (favorable) in a case in which the value of the resolution of the Example was smaller than that of the Comparative Example by no less than 0% and less than 20%”; or “C” (unfavorable) in a case in which the value of the resolution of the Example was greater than that of the Comparative Example.

### LWR

The resist pattern was observed from above the pattern by using the scanning electron microscope described above. The line width was measured at arbitrary fifty points in total, and from distribution of the measurement values, a 3 Sigma value was determined, which was defined as LWR (nm). A smaller value of the LWR indicates a better result.

The values of the LWR were compared between the radiation-sensitive compositions that differ from one another in terms of only the presence/absence or only either one of the type of the ligand (a) and the ligand (b). The LWR was evaluated by comparing values of the LWR of the radiation-sensitive composition of the Example and the radiation-sensitive composition of the Comparative Example to be used for comparison with this Example, and the evaluation was made to be: “A” (very favorable) in a case in which the value of the LWR of the Example was smaller than that of the Comparative Example by no less than 10%; “B” (favorable) in a case in which the value of the LWR of the Example was smaller than that of the Comparative Example by no less than 0% and less than 10%”; or “C” (unfavorable) in a case in which the value of the LWR of the Example was greater than that of the Comparative Example.

### Sensitivity

An exposure dose required for forming a 150-nm line-and-space pattern was measured, and this measurement value was defined as sensitivity (μC).

The values of the sensitivity were compared between the radiation-sensitive compositions that differ from one another in terms of only the presence/absence or only either one of the type of the ligand (a) and the ligand (b). The sensitivity was evaluated by comparing values of the sensitivity of the radiation-sensitive composition of the Example and the radiation-sensitive composition of the Comparative Example to be used for comparison with this Example, and the evaluation was made to be: “A” in a case in which the value of the sensitivity of the Example was less than that of the Comparative Example; and “B” in a case in which the value of the sensitivity of the Example was equal to or greater than that of the Comparative Example.

TABLE 3

| | | Radiation- | | | |
|---|---|---|---|---|---|
| | | sensitive | | | |
| | Radiation- | composition | | | |
| | sensitive | used for | | | |
| | composition | comparison | Resolution | LWR | Sensitivity |
| Example 1 | R-1 | CR-1 | A | A | B |
| Example 2 | R-2 | CR-2 | B | A | A |
| Example 3 | R-3 | CR-3 | A | A | B |
| Example 4 | R-4 | CR-4 | B | A | A |
| Example 5 | R-5 | CR-5 | A | A | A |
| Example 6 | R-6 | CR-6 | A | A | B |
| Example 7 | R-7 | CR-7 | B | A | A |
| Example 8 | R-8 | CR-8 | A | A | A |
| Example 9 | R-6 | CR-9 | A | A | A |

As is seen from the results shown in Table 3, the resist pattern-forming method in which each of the radiation-sensitive compositions of the Examples was used enabled formation of the resist pattern with higher resolution and less LWR in comparison with the cases in which the radiation-sensitive compositions of the Comparative Examples were used. In general, an exposure to an electron beam has been known to exhibit a similar tendency to a case of an exposure to an extreme ultraviolet ray. Therefore, from the results of the present Examples, it is speculated that formation of a resist pattern with high resolution and less LWR would be enabled also in the case of the exposure to an extreme ultraviolet ray.

The resist pattern-forming method and the radiation-sensitive composition of the embodiments of the present invention enable a resist pattern with high resolution and less LWR to be formed. The production method of a radiation-sensitive composition of the embodiment of the present invention enables such a radiation-sensitive composition to be easily obtained. Therefore, these can be suitably used for manufacture of semiconductor devices, for which microfabrication is expected to progress further hereafter, and the like.

Obviously, numerous modifications and variations of the present invention are possible in light of the above teachings. It is therefore to be understood that within the scope of the appended claims, the invention may be practiced otherwise than as specifically described herein.

What is claimed is:

1. A resist pattern-forming method comprising:
applying a radiation-sensitive composition directly or indirectly on a substrate to form a resist film;
exposing the resist film to an extreme ultraviolet ray or an electron beam; and
developing the resist film after the exposing, wherein the radiation-sensitive composition comprises:
a first complex comprising a metal atom and a first ligand coordinating to the metal atom;
a compound that gives a second ligand that differs from the first ligand; and
a second complex comprising the metal atom and the second ligand coordinating to the metal atom.

2. The resist pattern-forming method according to claim 1, wherein the radiation-sensitive composition further comprises a solvent.

3. The resist pattern-forming method according to claim 1, wherein the first ligand in the radiation-sensitive composition does not comprise a polymerizable group, and the second ligand comprises a polymerizable group.

4. The resist pattern-forming method according to claim 1, wherein a content of the compound in the radiation-sensitive composition is no less than 5 parts by mass and no greater than 700 parts by mass with respect to 100 parts by mass of the first complex.

5. The resist pattern-forming method according to claim 4, wherein the content of the compound in the radiation-sensitive composition is no less than 15 parts by mass and no greater than 600 parts by mass with respect to 100 parts by mass of the first complex.

6. The resist pattern-forming method according to claim 1, wherein
the first ligand and the second ligand in the radiation-sensitive composition are each derived from an acid, and
a pKa of the acid that gives the second ligand is less than a pKa of the acid that gives the first ligand.

7. The resist pattern-forming method according to claim 1, wherein, in the radiation-sensitive composition, a ratio of a number of moles of the second complex to a number of moles of the first complex is no less than 0.1 and no greater than 10.

8. The resist pattern-forming method according to claim 1, wherein the radiation-sensitive composition further comprises a radiation-sensitive acid generating agent.

9. A radiation-sensitive composition comprising:
a first complex comprising a metal atom and a first ligand coordinating to the metal atom;
a compound that gives a second ligand that differs from the first ligand; and
a second complex comprising the metal atom and the second ligand coordinating to the metal atom.

10. The radiation-sensitive composition according to claim 9, further comprising a solvent.

11. The radiation-sensitive composition according to claim 9, wherein the first ligand does not comprise a polymerizable group, and the second ligand comprises a polymerizable group.

12. The radiation-sensitive composition according to claim 9, wherein a content of the compound is no less than 5 parts by mass and no greater than 700 parts by mass with respect to 100 parts by mass of the first complex.

13. The radiation-sensitive composition according to claim 12, wherein the content of the compound is no less than 15 parts by mass and no greater than 600 parts by mass with respect to 100 parts by mass of the first complex.

14. The radiation-sensitive composition according to claim 9, wherein
the first ligand and the second ligand are each derived from an acid, and
a pKa of the acid that gives the second ligand is less than a pKa of the acid that gives the first ligand.

15. The radiation-sensitive composition according to claim 9, wherein a ratio of a number of moles of the second complex to a number of moles of the first complex is no less than 0.1 and no greater than 10.

16. The radiation-sensitive composition according to claim 9, further comprising a radiation-sensitive acid generating agent.

17. The radiation-sensitive composition according to claim 9 which is suitable for an exposure to an extreme ultraviolet ray or for an exposure to an electron beam.

18. A production method of a radiation-sensitive composition comprising mixing: a first complex comprising a metal atom and a first ligand coordinating to the metal atom; and a
compound that gives a second ligand that differs from the first ligand.
